(19) United States
(12) Patent Application Publication
(10) Pub. No.: US 2018/0299681 A1
(43) Pub. Date: Oct. 18, 2018

(54) FIT SYSTEM FOR WEARABLE DEVICE

(71) Applicant: Intel Corporation, Santa Clara, CA (US)

(72) Inventors: Mark J. Eastwood, Kentfield, CA (US); An Tran, Austin, TX (US); George Jie-Hyun Yoo, San Francisco, CA (US); Corbett Benjamin Schoenfelt, Austin, TX (US)

(21) Appl. No.: 15/485,900

(22) Filed: Apr. 12, 2017

(51) Int. Cl. G02B 27/02; A45F 5/00; G02C 11/00; G02C 3/00; H05K 5/00

(52) U.S. Cl. CPC G02B 27/028; A45F 5/00; H05K 5/0017; G02C 3/003; G02C 11/10

(57) ABSTRACT

A headgear securement system including a first support at a first portion of the headgear, a second support, separate from the first support, at a second portion of the headgear, a closure connected to the second support to lock the second support at a selected one of a plurality of fit settings and a compliance mechanism connected to the second support.

### TECHNICAL FIELD

This disclosure relates to wearable devices, and more particularly to wearable devices including a display device.

### BACKGROUND

Wearable devices, such as head-worn or head-mounted display devices (e.g., eyeglasses or “smart glasses,” headsets, helmets, etc.), have become increasingly integrated with many technologies and applications, including aviation, gaming, sports, medicine, and design. Wearable devices may include one or more small displays, with lenses and semi-transparent mirrors embedded in a viewing substrate (e.g., a smart glass lens, a visor, etc,) or attached to a movable member (e.g., a rotating arm, etc.) that may be selectively movable into a field of view.

The display may include, for example, a liquid crystal display (LCD), a liquid crystal on silicon (LCos) display, or an organic light-emitting diode (OLED) display. The display is configured to display video content (e.g., computer-generated imagery (CGI), virtual image, video, text, data, etc.). In some examples, the CGI is superimposed on a real-world view (i.e., what the wearer is viewing) by projecting the CGI through a partially reflective mirror to provide an augmented reality showing both the real-world as well as the projected video content. In another example, the CGI can be mixed into video from a video device, such as a camera, borne by the wearable device.

Wearable devices may include various systems, such as a communication system (e.g., Institute of Electrical and Electronics Engineers Standards Association (IEEE) 802.11ac standard, IEEE std. 802.11ac-2013, published Dec. 2, 2013, Bluetooth 4.0, near field communication (NFC) device, mobile network (GSM), global positioning system (GPS), etc.) and a camera system (e.g., a complementary metal-oxide-semiconductor (CMOS) sensor) powered by a power source (e.g., one or more batteries, etc.). The wearable devices may also include, for example, a system on a chip (SoC) or microcontroller to integrate the components and systems of the wearable device (e.g., camera, display, communications, etc.).

### BRIEF DESCRIPTION OF THE DRAWINGS

FIGS. 1A-1B depict, respectively, a disassembled view and an assembled view of an example wearable device including an example support system in accordance with teachings of this disclosure.

FIGS. 2A-2B depict, respectively, a perspective front view and a perspective rear view of an example compliance mechanism for the example support system of the example wearable device of FIGS. 1A-1B in accordance with teachings of this disclosure.

FIG. 3A is a disassembled view of the example compliance mechanism of FIGS. 2A-2B in accordance with teachings of this disclosure.

FIG. 3B is a disassembled view of the example compliance mechanism of FIG. 3A showing an example ratchet in accordance with teachings of this disclosure.

FIG. 3C is a rear view of the example compliance mechanism of FIG. 3B showing cam surfaces of the example ratchet in accordance with teachings of this disclosure.

FIG. 3D depicts is a cross-sectional view of the example compliance mechanism of FIGS. 2A-3B in accordance with teachings of this disclosure.

FIG. 4A is a rear perspective cut-away view of the example compliance mechanism of FIGS. 2A-3D showing a first example state of the example compliance mechanism in accordance with teachings of this disclosure.

FIG. 4B is a rear perspective cut-away view of the example compliance mechanism of FIG. 4A showing a second example state of the example compliance mechanism in accordance with teachings of this disclosure.

FIG. 4C is a rear perspective cut-away view of the example compliance mechanism of FIGS. 4A-4B showing a third example state of the example compliance mechanism in accordance with teachings of this disclosure.

FIG. 4D is a rear perspective cut-away view of the example compliance mechanism of FIGS. 4A-4C showing a fourth example state of the example compliance mechanism in accordance with teachings of this disclosure.

FIG. 5 is a flowchart representative of example machine readable instructions which may be executed to fabricate the example compliance mechanism of FIGS. 1A-4D for a wearable device in accordance with teachings of this disclosure.

The figures are not to scale. Instead, to clarify multiple layers and regions, the thickness of the layers may be enlarged in the drawings. Wherever possible, the same reference numbers will be used throughout the drawing(s) and accompanying written description to refer to the same or like parts. As used in this patent, stating that any part or material (e.g., a layer, film, area, or plate) is in any way positioned on (e.g., positioned on, located on, disposed on, or formed on, etc.) another part or material, means that the referenced part is either in contact with the other part, or that the referenced part is spaced apart from another part or material with one or more intermediate part(s) or material(s) intervening therebetween. Stating that any part is in contact with another part means that there is no intermediate part between the two parts.

### DETAILED DESCRIPTION

In the following description, numerous specific details are set forth to provide an understanding of various embodiments. However, it will be understood by those of ordinary skill in the art that the various embodiments may be practiced without the specific details. In other instances, well-known methods, procedures, components, and circuits have not been illustrated or described in detail so as not to obscure the particular embodiments.

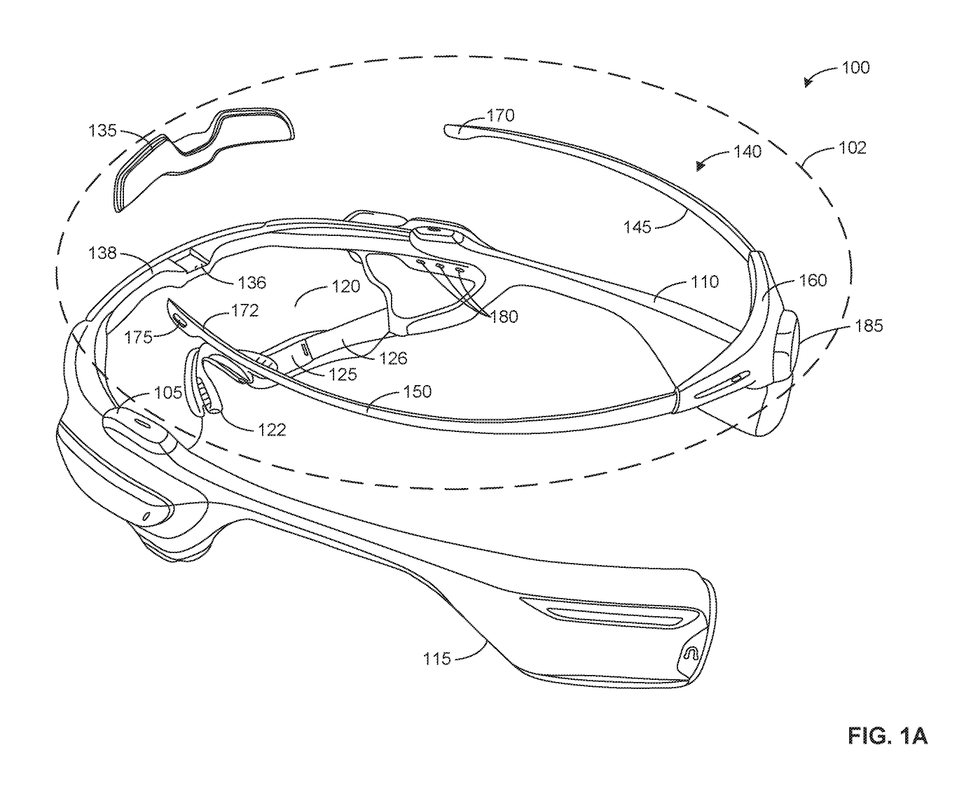

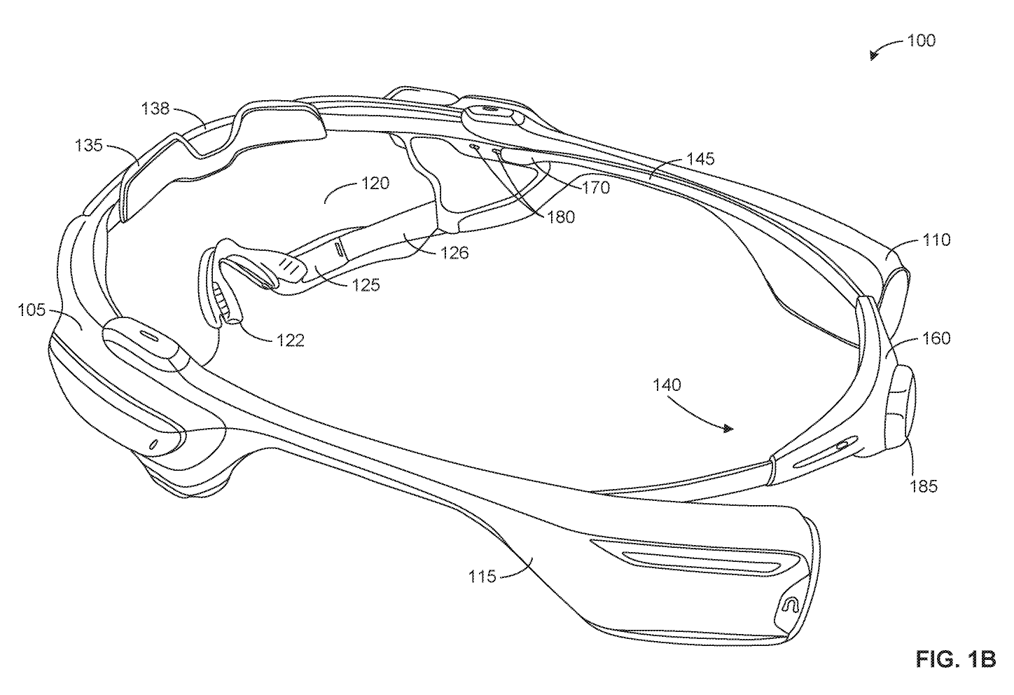

FIGS. 1A-1B depict, respectively, a disassembled view and an assembled view of an example wearable device 100 including an example support system 102. The example wearable device 100 is in the form of glasses or smart glasses. In other examples, the example wearable device 100 may include, for example, a headset or a helmet.

The example wearable device 100 includes an example frame 105 having an example first frame arm 110 and an example second frame arm 115 and an example lens 120 having an example nosepiece 122. The example nosepiece 122, which may be a unitary nosepiece or may include two or more separate pads, is attached to the example frame 105 and/or example lens 120 and supports the example frame 105 and/or example lens 120 on the nose of the wearer, helping to maintain the frame the example frame 105 and/or example lens 120 in a desired position. The example first frame arm 110 and an example second frame arm 115 extend rearwardly from portion of the example frame 105 bearing the example lens 120 and are configured to extend over the ears of the wearer to rest between the helix of the ear and the head. The example first frame arm 110 and the example second frame arm 115 may be fixed relative to the example frame 105, or may be connected to the example frame 105 via a hinged connection. The example first frame arm 110, example second frame arm 115 and example nosepiece 122 provide three points of contact with the wearer's head, which provide a stable platform for securement of the example wearable device 100.

In some examples, the example lens 120 includes two lenses. The example lens 120 may include any optically transmissive element that focuses incident light, disperses incident light and/or passes incident light without refraction (focusing) or dispersion. For example, the lens 120 may include a plastic protective element. In some examples, the example lens 120 is fixed to the example frame 105. In some examples, the example lens 120 is removable and may be replaced with a different lens 120.

The example wearable device 100 includes a display 125 attached to an arm 126 that may be fixed and/or movable (e.g., rotatable about one or more axes, positionable to one of a plurality of different settings, etc.). The display may include, for example, a LCD display, a LCos display, an OLED display, or an active-matrix organic light-emitting diode (AMOLED) display.

The example support system 102 includes an example first support 135 and an example second support 140. The example first support 135 is provided at a first portion of the example wearable device 100 and the example second support 140, which is separate from the example first support 135, is provided at a second portion of the example wearable device 100. In the example of FIGS. 1A-1B, the example first support 135 is provided at a fore (e.g., frontal, etc.) region of the wearable device 100 and the example second support 140 is provided at a lateral region and an aft (e.g., rear) region of the example wearable device 100.

The example first support 135 is attached (e.g., fixed, removably attached, etc.) to an example bridge 136 of the example wearable device 100. In some examples, the example first support 135 is attached to the example bridge 136 via a mechanical connection. In some examples, the mechanical connection between the example first support 135 and the example bridge 136 includes a male attachment member (e.g., a key, etc.) on the example first support 135 configured to matingly and removably engage an example female attachment member 138 (e.g., a slot, etc.) formed in the example bridge 136. In some examples, the example first support 135 is attached to the example bridge 136 by a mechanical attachment member, such as a screw, or by bonding, such as thermal bonding or adhesive bonding. In some examples, a resilient material, such as a silicon gel cushion, closed cell sponge rubber, a foam rubber or a latex foam rubber, is provided as a brow pad on an inner surface of the example first support 135 to more comfortably engage the wearer's brow or forehead. In some examples, the example first support 135 may include a plurality of separate support members (e.g., two support members) attached to different portions of the example bridge 136. In some examples, the example wearable device 100 is provided with a plurality of different first support members 135 of different sizes (e.g., surface areas, etc.), different geometries/shapes/angles and/or different materials. In some examples, a removable first support 135 permits a plurality of different wearers (e.g., different wearers in an Enterprise call center, etc.) to customize a single wearable device 100 to a desired head shape (e.g., protruding brow, flat brow, etc.) and size.

In some examples, the example second support 140 includes an example first arm 145 and an example second arm 150 connected at a first end to an example compliance mechanism 160 and connected at a second end to the example frame 105 or to the example first frame arm 110 and the example second frame arm 115. In some examples, a second end 170 of the example first arm 145 and a second end 172 of the example second arm 150 are attached (e.g., fixed, removably attached, etc.) to lateral portions of the example frame 105. In some examples, the second end 170 of the example first arm 145 and the second end 172 of the example second arm 150 are attached to the example frame 105 at aft or rearward portions of the example frame 105, such as at rear portions of the example first arm 110 and example second arm 115. The second end 170 of the example first arm 145 and the second end 172 of the example second arm 150 each include a second connector 175 dimensioned to connect to a matingly configured attachment member 180 of the example frame 105 or of the example first arm 110 and the example second arm 115. In FIGS. 1A-1B, the example frame 105 includes a plurality of attachment members 180 to facilitate adjustment of a fit of the example wearable device 100 to suit the needs of the wearer. In some examples, the front one of the plurality of attachment members 180 may correspond to a small setting, the middle one of the plurality of attachment members 180 may correspond to a medium setting and the rear one of the plurality of attachment members 180 may correspond to a large setting. In some examples, additional attachment members are provided to permit further refinement of fit. In some examples, in lieu of a plurality of discrete attachment members 180, a movable attachment member (e.g., a lockable sliding element, etc.) may be provided.

In the configuration shown in FIG. 1B, the example first support 135 is to support a first portion of a weight of the example wearable device 100 by directing a first portion of the weight to a wearer's frontal bone and the example second support 140 is to support a second portion of the weight of the example wearable device 100 by directing a second portion of the weight to the wearer's parietal bone, temporal bones and/or occipital bone. In use, following a selection of a proper fit for the wearer by attaching the second connector 175 of the second end 170 of the example first arm 145 to a selected one of the plurality of attachment members 180 on a first side of the frame and attaching the second connector 175 of the second end 170 of the second end 172 of the example second arm 150 to a selected one of the plurality of attachment members 180 on a second side of the frame, a wearer is able to tighten the example second support 140, via an example control member 185. In the example of FIGS. 1A-1B, the example control member 185 includes a rotatable knob. In other examples, the example control member 185 includes a hook and loop closure or a snap closure. Tightening of the example second support 140 via the example control member 185 causes an increase in radial pressure and a transfer of weight away from nose and ears. In some examples, the example second support 140 is able to be tightened, via the example control member 185, to relieve all of the weight of the example wearable device 100 from the nasal bones, by lifting the example nosepiece 122 off of the nasal bones, and from the ears, by lifting the example first frame arm 110 and the example second frame arm 115 off of the ears. In some examples, when the example wearable device 100 is worn and the example second support 140 tightened, the weight of the example wearable device 100 is entirely supported by the wearer's frontal bone and parietal bone, temporal bones and/or occipital bone. In some examples, a weight of example wearable devices 100 is between 30-60 g, between 60 g-100 g, or even over 100 g (e.g., 470 g, 555 g, etc.). The example support system 102 including the example first support 135 and the example second support 140 provides enhanced control of weight distribution of the example wearable device 100, which advantageously increases comfort for the wearer over periods of extended wear (e.g., 3 or more hours) via its fore-aft clamping of the example wearable device 100 to the wearer's head, which relieves the nose and ears of any weight. The example support system 102 including the example first support 135 and the example second support 140 also enables removal and/or replacement of the example lens 120 without removal of the example wearable device 100.

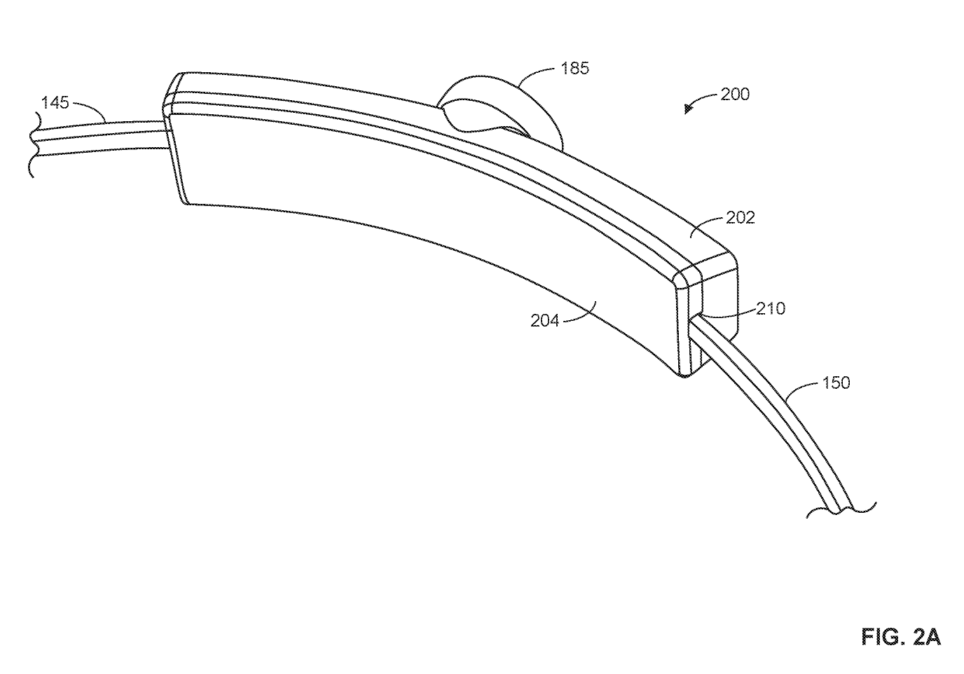

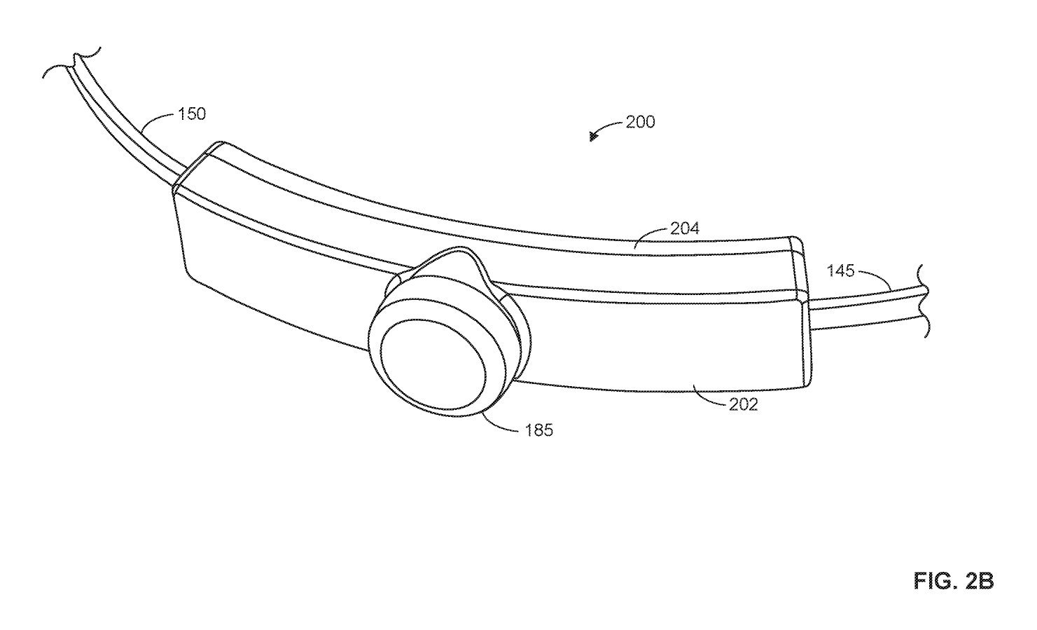

FIGS. 2A-2B depict, respectively, a perspective front view and a perspective rear view of an example compliance mechanism 200 for the example support system 102 of the example wearable device 100 of FIGS. 1A-1B. FIG. 2A shows the example first arm 145 and the example second arm 150 of the example support system 102 of FIGS. 1A-1B extending into the example compliance mechanism 200 through openings 210 in the example rear housing 202 and/or example front housing 204. The example rear housing 202 is attached to the example front housing 204 via, for example, a snap-fit connection (e.g., male/female connectors), mechanical fasteners (e.g., screws, clips, snaps, etc.), a welded connection (e.g., ultrasonic welded connection, friction welded connection, laser welded connection, etc.), or an adhesive connection. FIG. 2A, and more particularly FIG. 2B, show an example control member 185 in the form of an example rotatable knob extending from the example rear housing 202.

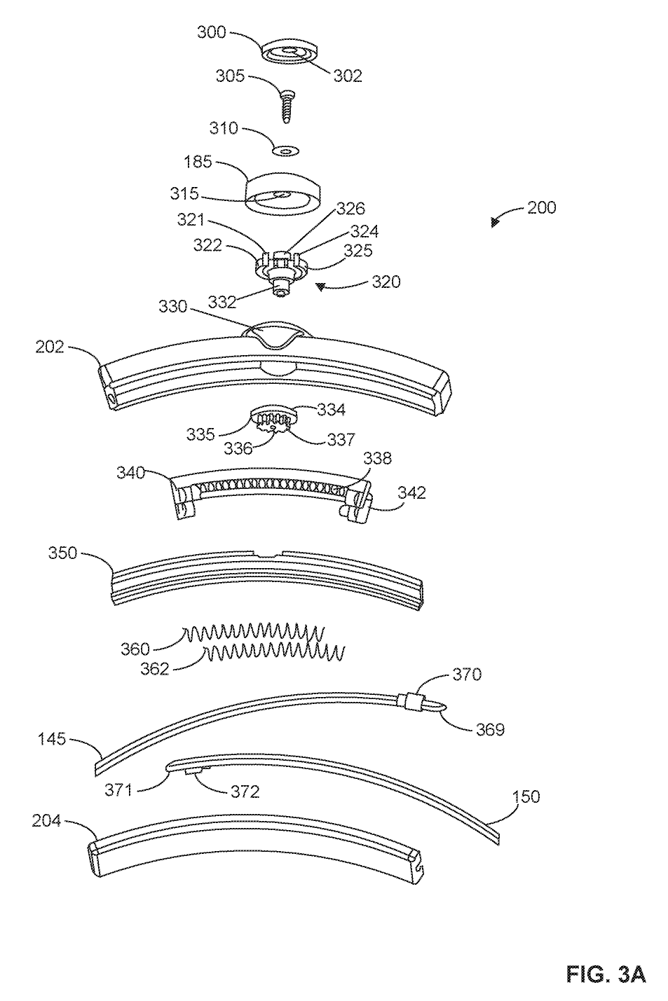

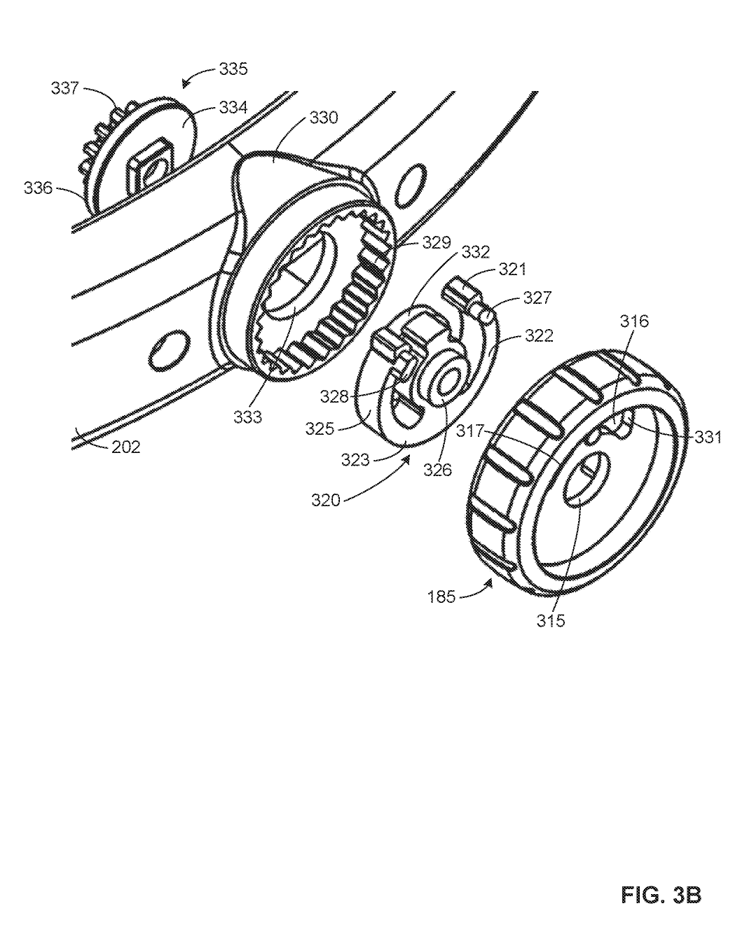

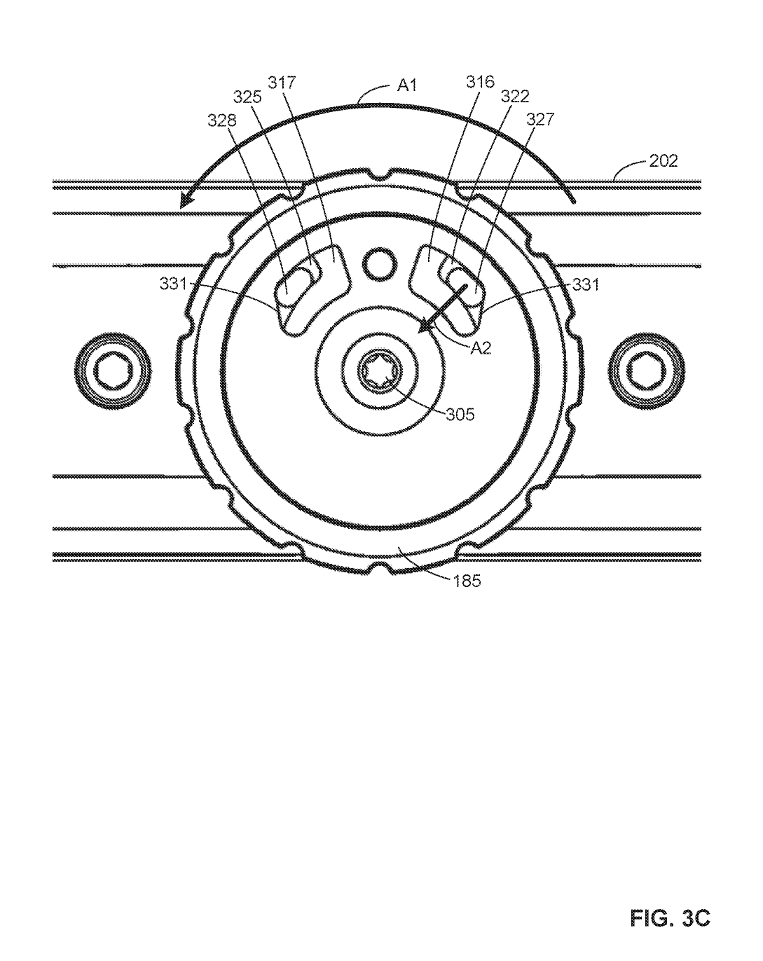

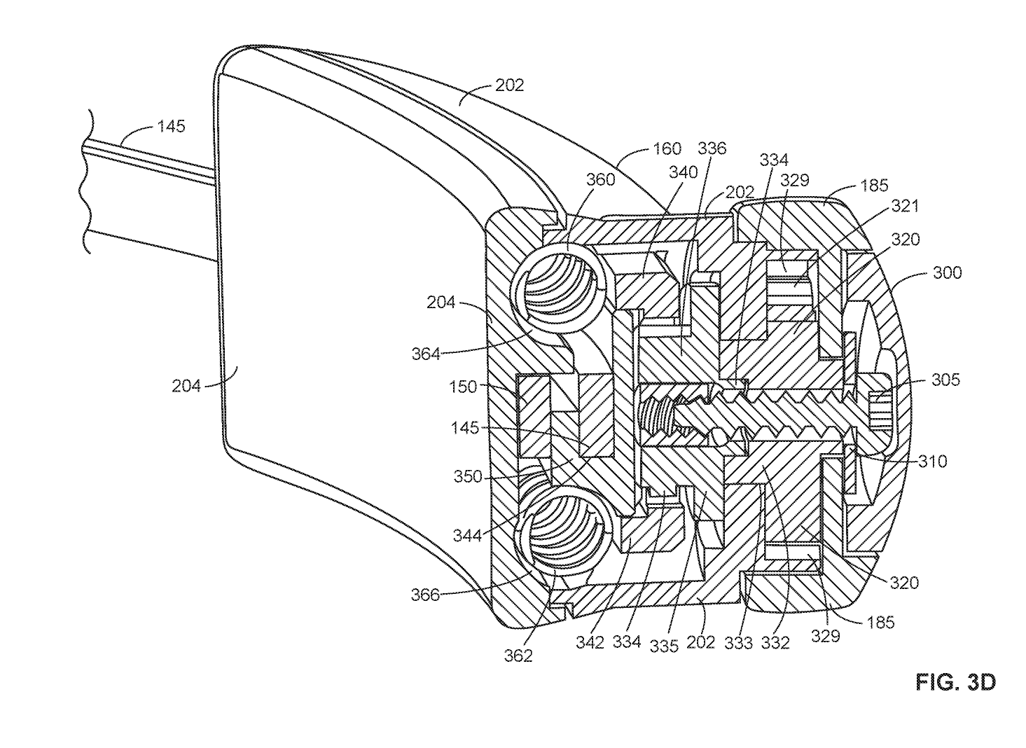

FIGS. 3A-3D present views of the example compliance mechanism 200 of FIGS. 2A-2B. Starting at the top of FIG. 3A, an example knob cap 300 is attached to the control member 185, such as by a snap-fit connection, a threaded connection or an adhesive. An opening or recess 302 in the example knob cap 300 accommodates a head of example screw 305. The example opening or recess 302 may include a recess in the knob cap 300 or a through-hole. The example control member 185 includes, as shown in FIGS. 3A-3B, an example through hole 315 and example through holes 316. In some examples, the example through hole 315 and example through holes 316, 317 are, instead, recesses within the example control member 185. The example screw 305 is inserted through an example washer 310 to attach the example control member 185 to an example ratchet 320.

As shown in FIGS. 3A-3B, the example ratchet 320 includes an example first pawl 321 attached to an example first spring arm 322 that is cantilevered from an example base portion 323 of the example ratchet 320. The example ratchet 320 also includes an example second pawl 324 attached to a second spring arm 325 that is cantilevered from the example base portion 323 of the example ratchet 320. At a first end of the example ratchet 320, an example first connector 326 extends from the example base portion 323 of the example ratchet 320 to connect to the example through hole 315 of the example control member 18, such as by an interference fit. Also at the first end of the example ratchet 320, an example first spring arm cam 327 extends from the example first spring arm 322 and into the example through hole 316 of the example control member 185 and an example second spring arm cam 328 extends from the second spring arm 325 and into the example through hole 317 of the example control member 185. The example through hole 316 includes an example cam surface 331 to act upon and bias the first spring arm cam 327 and the example through hole 317 includes an example cam surface 331 to act upon and bias the second spring arm cam 328, as described below.

The example first pawl 321 and the example second pawl 324 are configured to cooperatively engage example teeth 329 formed on an interior surface of the example rear housing 202, or extension thereof, such as is shown in FIG. 3B where the example teeth 329 are formed in an example boss 330. In other examples, the example teeth 329 are formed within the example compliance mechanism 200. In operation, depending on a direction of rotation, one of the example first spring arm 322 or the example second spring arm 325 will bind when back-driven due to the pressure angle between a pawl 321, 324 of the respective one of the spring arms 322, 325 and the example teeth 329, effectively locking the example ratchet 320 in place against unintended rotation. Manual rotation of the example control member 185 in a given direction to tighten (e.g., clockwise rotation) or to loosen (e.g., clockwise rotation) the example second support 140 overcomes a radially outward force exerted by the one of the example first spring arm 322 or the example second spring arm 325 on the example teeth 329 to bias the pawl 321, 324 engaging the example teeth 329 toward a center of rotation and away from the example teeth 329, unlocking the example ratchet 320 from the example teeth 329 and allowing the example control member 185 and the example ratchet 320 to rotate in the direction urged by the wearer or user. The other one of the pawl 321, 324 of the other one of the example first spring arm 322 or the example second spring arm 325 then acts as a detent to resist, but not prevent, rotation. For example, as shown in FIG. 3C, a counterclockwise rotation of the control member 185 as indicated by arrow A1 causes the example cam surface 331 to contact the example cam 327 of the example first spring arm 322 and bias it in a counterclockwise direction. Responsive to the urging of the example cam surface 331, the example cam 327 and a distal end of the example first spring arm 322 is deflected radially, along arrow A2, toward a center of rotation and the example pawl 321 is urged in a direction away from a face of a tooth of the example teeth 329 to which it is engaged. In some examples, the example cams 327, 328 and the example cam surfaces 331 are selected to bias the example pawls 321, 324 in a direction substantially perpendicular to a surface of the example teeth 329 to eliminate sliding between the example pawls 321, 329 and the example teeth 329.

As shown in FIG. 3A and FIG. 3D, for example, a second end 332 of the example ratchet 320 is disposed through an example through hole 333 in the example rear housing 202 and is attached (e.g., interference fit, adhesive bond, connected via example screw 305, threaded connection, etc.) to a first end 334 of an example pinion gear 335 having, on an example second end 336, example teeth 337. Rotation of the example ratchet 320 causes a rotation of the example pinion gear 335. In the example of FIGS. 3A-3D, the example second end 332 of the example ratchet 320 and the example first end 334 of the example pinion gear 335 are attached across the example through hole 333. In other examples, the example second end 332 of the example ratchet 320 extends entirely through the example through hole 333 to attach to the example first end 334 of the example pinion gear 335 on an interior of the example rear housing 202. In yet other examples, the example first end 334 of the example pinion gear 335 extends entirely through the example through hole 333 to attach to the example second end 332 of the example ratchet 320 on an exterior of the example rear housing 202.

The example teeth 337 of the example pinion gear 335 engage correspondingly configured mating example teeth 338 of an example first gear rack 340 rack disposed on a first side of the example pinion gear 335 and an example second gear rack 342 disposed on a second side of the example pinion gear 335 opposite the first side of the example pinion gear 335. Rotation of the example pinion gear 335 causes, via teeth 337, 338, a corresponding translation of the example first gear rack 340 in a first direction and causes a translation of the example second gear rack 342 in a second direction opposite to the first direction.

An example guide member 350 is provided in the example compliance mechanism 200 to guide movement of the example first arm 145 and the example second arm 150 as they translate relative to the example compliance mechanism 200. In FIG. 3A and FIG. 3D, the example guide member 350 guides the example first arm 145 within an example groove 344. In FIG. 3D, the example second arm 145 is shown to be constrained to move between the example guide member 350 and the example front housing 204.

As shown in FIG. 3D, the example guide member 350 is positioned between the example first gear rack 340 and the example second gear rack 342, which positions the example first arm 145 and the example second arm 150 along a middle portion of the example compliance mechanism 200. A first resilient element 360 (e.g., a spring, etc.) is disposed on a first side of the example compliance mechanism 200 (e.g., an upper side) and a second resilient element 362 (e.g., a spring, etc.) is disposed on a second side of the example compliance mechanism 200 (e.g., a lower side). In some examples, the example first resilient element 360 is at least partially retained within a groove 364 formed in the example front housing 204 and the example second resilient element 362 is at least partially retained within a groove 366 formed in the example front housing 204.

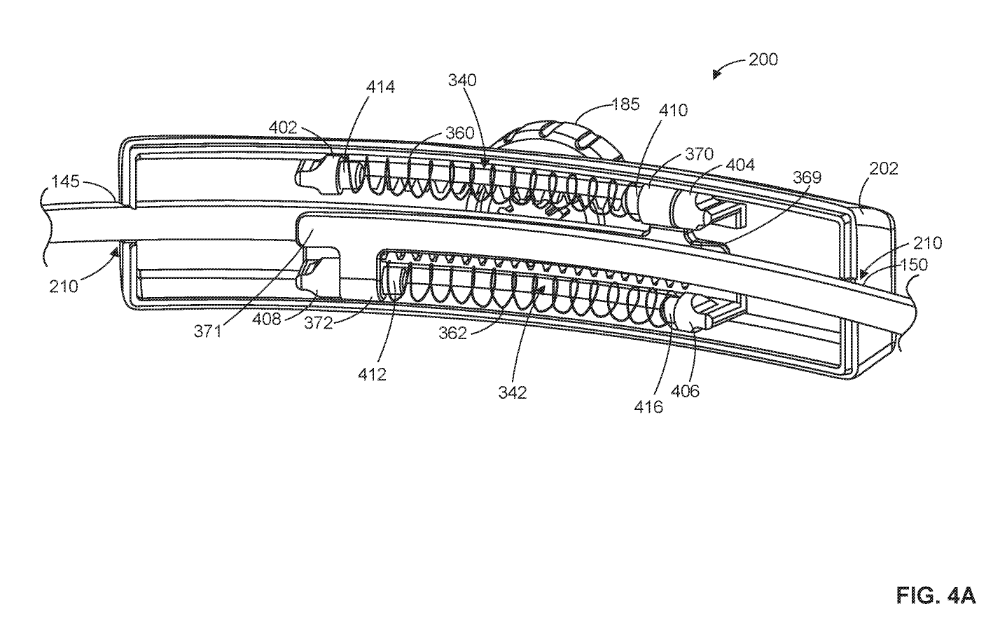

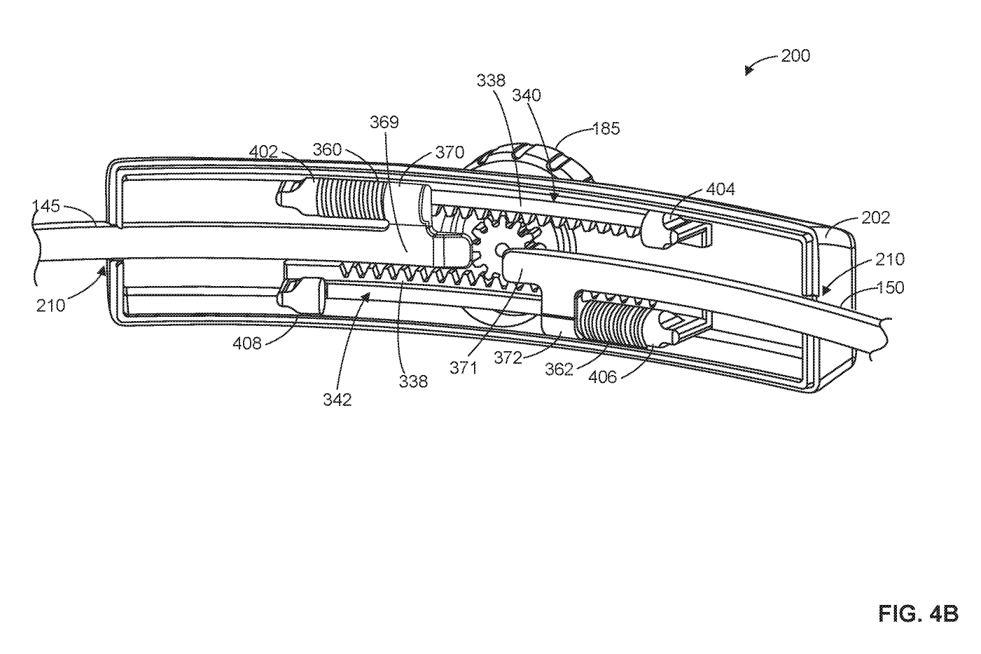

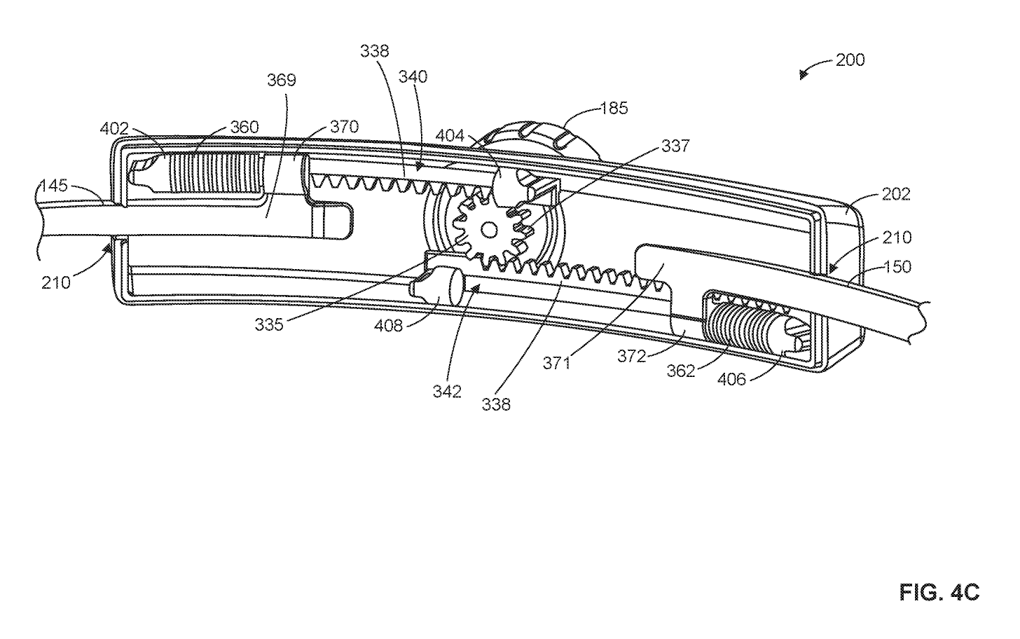

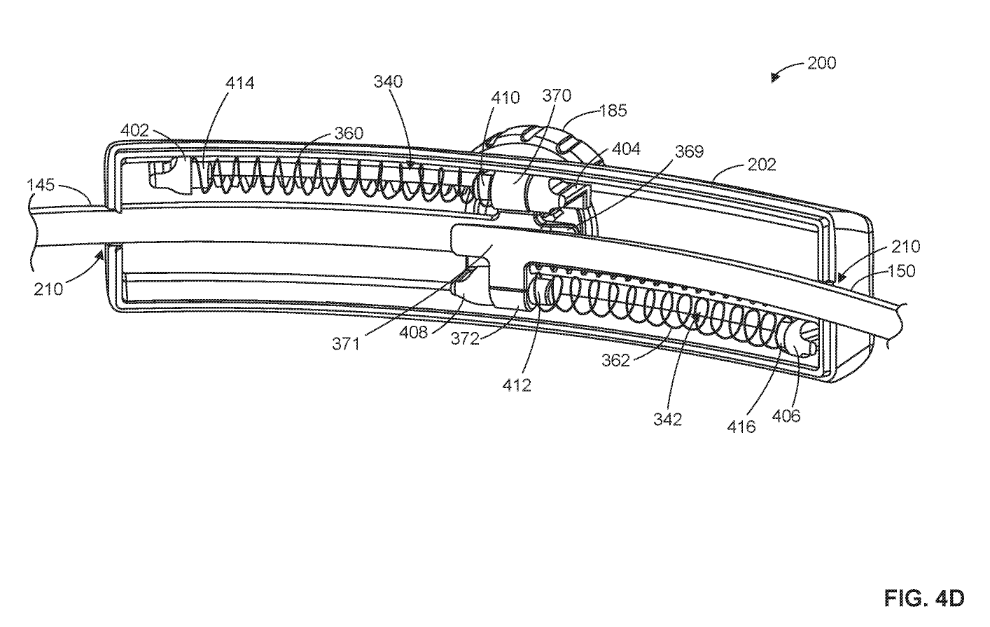

Turning to FIG. 3A, the example first arm 145 is shown to include, at an example first end 369, a first connector 370 and the example second arm 150 is shown to include, at an example first end 371, a first connector 372. The first connectors 370, 372 are discussed below in relation to FIGS. 4A-4D.

Additional details illustrating the design and the operation of the example compliance mechanism 200 are shown in FIGS. 4A-4D which depict, respectively, rear perspective cut-away views of the example compliance mechanism of FIGS. 2A-3D (i.e., the example front housing 204 is removed in FIGS. 4A-4D for clarity). FIGS. 4A-4D show different example states of the example compliance mechanism 200.

FIG. 4A shows the example compliance mechanism 200 in a first state where the example first gear rack 340 and the example second gear rack 342 are centrally positioned within the example compliance mechanism 200 with the example first arm 145. For instance, this first state may correspond to a first wearer-selected setting of a position of the example first gear rack 340 and the example second gear rack 342 wherein a first wearer has donned an example wearable device 100 (see, e.g., FIG. 1B) and manipulated the example control member 185 to tighten the example second support 140 to provide a desired level of fore/aft support and/or a desired positioning (e.g., off of the nose and/or ears) for the first wearer.

In FIG. 4A, the example first resilient element 360 is positioned in the example first gear rack 340 between the example first connector 370 at the first end 369 of the example first arm 145 and an example first base member 402 of the first gear rack 340. The example first resilient element 360 biases the example first connector 370 of the example first arm 145 in a direction away from the example first base member 402. Movement of the example first arm 145 in a direction away from the example first base member 402 along a path defined by the example guide member 350 is stopped by an example second base member 404 of the first gear rack 340. Likewise, the example second resilient element 362 is shown to be positioned in the example second gear rack 342 between the example first connector 372 at the first end 371 of the example second arm 150 and an example first base member 406 of the second gear rack 342. The example second resilient element 362 biases the example first connector 372 of the example second arm 150 in a direction away from the example first base member 406. Movement of the example second arm 150 in a direction away from the example first base member 406 along a path defined by the example guide member 350 is stopped by an example second base member 408 of the second gear rack 342.

In some examples, the example first resilient element 360 is attached to the example first connector 370 and/or the example first base member 402. For instance, in the example of FIGS. 4A-4D, the first example connector 370 includes an example first post 410 about which the example first resilient element 360 is disposed and the example first resilient element 360 is attached (e.g., via mechanical connection and/or adhesive connection) to the example first post 410 and/or a surface of the example first base member 402. In some examples, the example second resilient element 362 is attached to the example first connector 372 and/or the example first base member 406. For instance, in the example of FIGS. 4A-4D, the example second connector 372 includes an example first post 412 about which the example second resilient element 362 is disposed and the second resilient element 362 is attached to the example first post 412 and/or a surface of the example first base member 406. In the example of FIGS. 4A-4D, the example first base member 402 of the first example gear rack 340 includes an example second post 414 about which an end of the first resilient element 360 is disposed, with the first resilient element 360 being attached to the example second post 414 and/or a surface of the example first base member 402. Likewise, the example first base member 406 of the second example gear rack 342 includes an example second post 416 about which an end of the second resilient element 362 is disposed, with the second resilient element 362 being attached to the example second post 416 and/or a surface of the example first base member 406.

FIG. 4B shows the example compliance mechanism 200 of FIG. 4A in a second state where the example first gear rack 340 and the example second gear rack 342 are centrally positioned within the example compliance mechanism 200 with the example first arm 145 and the example second arm 150 in an extended state. For instance, this second state may correspond to a condition wherein the first wearer of the wearable device of FIG. 4A is doffing (e.g., removing) the example wearable device 100 (see, e.g., FIG. 1B) and is pulling on the example wearable device 100, causing an extension of the example first arm 145 and the example second arm 150 sufficient to enable doffing without requiring the first wearer to manipulate the control member 185 to change a setting of the ratchet 320 or closure to unlock and loosen the example second support 140. As another example, this second state may correspond to a condition wherein the first wearer of the wearable device of FIG. 4A had previously doffed the example wearable device 100 and is again donning the example wearable device 100 by forcing an extension of the example first arm 145 and the example second arm 150 sufficient to enable donning of the example wearable device 100 without requiring the first wearer to manipulate the control member 185 to change a setting of the ratchet 320 or closure to unlock and loosen the example second support 140.

In FIG. 4B, the example first resilient element 360, positioned between the example first connector 370 and the example first base member 402 is compressed with the example first arm 145 in the extended state. In this second state, the example first arm 145 biases the example first connector 370 toward the example first base member 402 until the example first resilient element 360 reaches a solid height state at which point the example first resilient element 360 is not capable of further deformation. For instance, where the example first resilient element 360 is a spring, the second state corresponds to a point at which each coil of the spring is brought into contact with the adjacent coils, as is represented in the example of FIG. 4B. Likewise, the example second resilient element 362, positioned between the example first connector 372 and the example first base member 406 is compressed with the example second arm 150 in the extended state. In this second state, the example second arm 150 biases the example first connector 372 toward the example first base member 406 until the example second resilient element 362 reaches a solid height state at which point the example second resilient element 362 is not capable of further deformation.

FIGS. 4A-4B illustrate that, for a fixed position of the example first gear rack 340 and the example second gear rack 342, the example first arm 145 and the example second arm 150 are free to move between the first state (FIG. 4A) corresponding to a default position and the second state (FIG. 4B) corresponding to an extended position of the example first arm 145 and the example second arm 150. This permits the example compliance mechanism 200 to accommodate movement of the example first arm 145 and the example second arm 150 and of the example second support 140 during donning and doffing of the example wearable device 100. Consequently, the wearer is not required to adjust the ratchet 320 or other closure from the wearer-selected fit setting (e.g., a selected position of the example first gear rack 340 and the example second gear rack 342 in FIGS. 4A-4B).

FIG. 4C shows the example compliance mechanism 200 in a third state where the example first gear rack 340 and the example second gear rack 342 are laterally displaced to a maximum extent within the example compliance mechanism 200. For instance, this third state may correspond to a second wearer-selected setting for a position of the example first gear rack 340 and the example second gear rack 342 wherein a second wearer has donned an example wearable device 100 (see, e.g., FIG. 1B) and manipulated the example control member 185 to tighten the example second support 140 to provide a desired level of fore/aft support and/or a desired positioning (e.g., off of the nose and/or ears) for the second wearer. Save for the initial positioning of the example first gear rack 340 and the example second gear rack 342, the example of FIG. 4C is the same as the example of FIG. 4A. Likewise, save for the initial positioning of the example first gear rack 340 and the example second gear rack 342, the example of FIG. 4D is the same as the example of FIG. 4B. FIGS. 4C-4D illustrate that, for a fixed position of the example first gear rack 340 and the example second gear rack 342, the example first arm 145 and the example second arm 150 are free to move between the third state (FIG. 4C) and the fourth state (FIG. 4D). This permits the example compliance mechanism 200 to accommodate movement of the example first arm 145 and the example second arm 150 and of the example second support 140 during donning and doffing of the example wearable device 100. Consequently, the wearer is not required to adjust the ratchet 320 or other closure from the wearer-selected fit setting (e.g., a selected position of the example first gear rack 340 and the example second gear rack 342 in FIGS. 4A-4D).

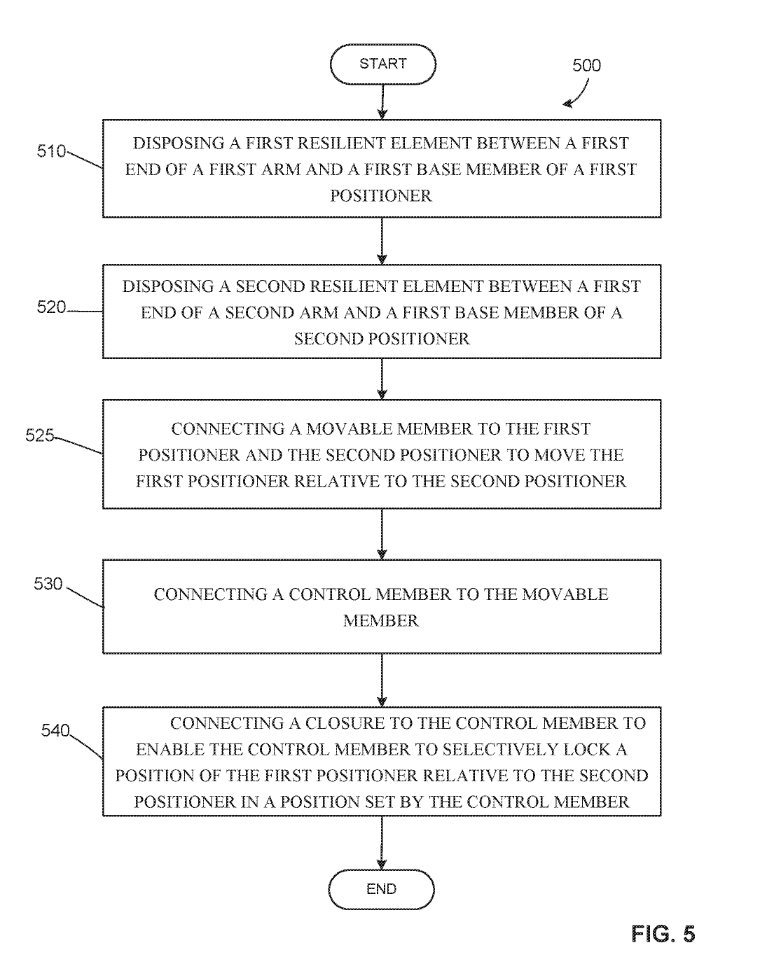

FIG. 5 shows is a flowchart 500 representative of example machine readable instructions which may be executed to fabricate the example compliance mechanism 160, 200 of FIGS. 1A-4D for an example wearable device 100.

At block 510, a first resilient element is disposed between a first end of a first arm and a first base member of a first positioner in a first portion of a compliance mechanism. In some examples, the first positioner includes a first gear rack 340, the first base member 402, and the second base member 404 of FIGS. 3A-4D. For instance, in relation to the examples of FIGS. 3A-4D, a first resilient element 360 is disposed between a first end 369 of a first arm 145 and a first base member 402 of a first gear rack 340 in a first portion of a compliance mechanism 200. The first end 369 of the first arm 145 is disposed to translate between the first base member 402 of the first gear rack 340 and a second base member 404 of the first gear rack 340 so that translation of the first arm 145 toward the first base member 402 is against a bias of the first resilient element 360. In some examples, the first resilient element 360 and the second resilient element 362 include a spring.

At block 520, a second resilient element is disposed between a first end of a second arm and a first base member of a second positioner in a second portion of a compliance mechanism. For instance, a second resilient element 362 is disposed between a first end 371 of a second arm 150 and a first base member 406 of a second gear rack 342 in a second portion of a compliance mechanism 200. The first end 371 of the second arm 150 is disposed to translate between the first base member 406 of the second gear rack 342 and a second base member 408 of the second gear rack 342 so that translation of the second arm 150 toward the first base member 406 is against a bias of the second resilient element 362.

At block 525, a movable member is connected to the first positioner and the second positioner to move the first positioner relative to the second positioner. In some examples, the movable member is the example pinion 335.

At block 530, the control member is connected to the movable member. In some examples, this includes the connecting of the example control member 185 to the example pinion 335, directly or through one or more intermediate parts. In some examples, the first positioner (e.g., the first gear rack 340, etc.) and the second positioner (e.g., the second gear rack 342, etc.) have separate control members.

At block 540, a closure is connected to the control member to enable the control member to selectively lock a position of the first positioner relative to the second positioner in a position set by the control member. In some examples, the closure includes the example ratchet 320, which is connected to the example control member 185 to lock a position of the first positioner (e.g., the first gear rack 340, etc.) relative to the second positioner (e.g., the second gear rack 342, etc.) in a position set by the movable element (e.g., pinion 335).

Example 1 is a headgear securement system including a first support at a first portion of the headgear, a second support, separate from the first support, at a second portion of the headgear, a closure connected to the second support to lock the second support at a selected one of a plurality of fit settings and a compliance mechanism connected to the second support.

Example 2 includes the headgear securement system as defined in Example 1, wherein the compliance mechanism includes one or more resilient elements to permit displacement of the second support to facilitate donning and doffing of the headgear with the closure being locked at a selected fit setting.

Example 3 includes the headgear securement system as defined in any of Examples 1-2, wherein the headgear includes a display device.

Example 4 includes the headgear securement system as defined in any of Examples 1-3, wherein the closure includes a hook and loop closure, a snap closure, or a ratchet.

Example 5 includes the headgear securement system as defined in any of Examples 1-4, wherein the second support includes a first arm having a first end connected to the compliance mechanism and a second end connected to the headgear and includes a second arm having a first end connected to the compliance mechanism and a second end connected to the headgear.

Example 6 includes the headgear securement system as defined in any of Examples 1-5, wherein the closure includes the compliance mechanism.

Example 7 includes the headgear securement system as defined in any of Examples 1-6, wherein the one or more resilient elements includes a first resilient element and a second resilient element, wherein the first resilient element is disposed between a first end of the first arm and a first end of a first positioner in a first portion of the compliance mechanism, wherein the first end of the first arm is disposed to translate between the first end of the first positioner and a second end of the first positioner, wherein the second resilient element is disposed between a first end of the second arm and a first end of a second positioner in a second portion of the compliance mechanism, and wherein the first end of the second arm is disposed to translate between the first end of the second positioner and a second end of the second positioner.

Example 8 includes the headgear securement system as defined in any of Examples 1-7, wherein the first positioner includes a first gear rack and the second positioner includes a second gear rack.

Example 9 includes the headgear securement system as defined in any of Examples 1-8, further including a pinion operatively engaging the first gear rack and the second gear rack, a ratchet, and a rotatable control member controlling movement of the ratchet and the pinion, wherein rotation of the rotatable control member rotates the pinion to cause a lateral translation of the first gear rack in a first direction and a lateral translation of the second gear rack in a second direction.

Example 10 includes the headgear securement system as defined in any of Examples 1-9, wherein the first resilient element is coupled at a first end to a first end of the first arm and wherein the second resilient element is coupled at a first end to a first end of the second arm.

Example 11 includes the headgear securement system as defined in any of Examples 1-10, wherein the first resilient element includes a first spring and wherein the second resilient element includes a second spring.

Example 12 includes the headgear securement system as defined in any of Examples 1-11, wherein the first portion of the headgear includes a fore region of the headgear and the second portion of the headgear includes an aft region of the headgear.

Example 13 includes the headgear securement system as defined in any of Examples 1-12, wherein the first support is to support a first portion of a weight of the headgear by directing a first portion of the weight to a frontal bone of a wearer and wherein the second support is to support a second portion of the weight of the headgear by directing a second portion of the weight to at least one of a parietal bone, temporal bones or an occipital bone of the wearer.

Example 14 includes the headgear securement system as defined in any of Examples 1-13, wherein the second end of the first arm is connected to the headgear at a first attachment point and wherein the second end of the second arm is connected to the headgear at a second attachment point.

Example 15 includes the headgear securement system as defined in any of Examples 1-14, wherein the first attachment point is provided at a first lateral portion of the headgear or a first rear portion of the headgear and wherein the second attachment point is provided at a second lateral portion of the headgear or a second rear portion of the headgear.

Example 16 includes the headgear securement system as defined in any of Examples 1-15, wherein the first support, or a portion thereof, is removably attached to the headgear to permit replacement of the first support or to permit reconfiguration of the first support.

Example 17 is a headgear securement system including a first support means at a first portion of the headgear, a second support means, separate from the first support means, at a second portion of the headgear, a closure means connected to the second support means to lock the second support means at a selected one of a plurality of fit settings, and a compliance means connected to the second support means.

Example 18 includes the headgear securement system as defined in Example 17, wherein the compliance means includes a resilient means to permit displacement of the second support means to facilitate donning and doffing of the headgear with the closure means being locked at a selected fit setting.

Example 19 includes the headgear securement system as defined in any of Examples 17-18, wherein the headgear includes a display means.

Example 20 includes the headgear securement system as defined in any of Examples 17-19, wherein the second support means includes a first arm having a first end connected to the compliance means and a second end connected to the headgear and wherein the second support means includes a second arm having a first end connected to the compliance means and a second end connected to the headgear.

Example 21 includes the headgear securement system as defined in any of Examples 17-20, wherein the closure means includes the compliance means.

Example 22 includes the headgear securement system as defined in any of Examples 17-21, wherein the first end of the first arm is connected to a first resilient means in a first portion of the compliance means and wherein the first end of the second arm is connected to a second resilient means in a second portion of the compliance means.

Example 23 includes the headgear securement system as defined in any of Examples 17-22, wherein the first portion of the headgear includes a fore region of the headgear and the second portion of the headgear includes an aft region of the headgear.

Example 24 includes the headgear securement system as defined in any of Examples 17-23, wherein the first support means is to support a first portion of a weight of the headgear by directing a first portion of the weight to a frontal bone of a wearer and wherein the second support means is to support a second portion of the weight of the headgear by directing a second portion of the weight to at least one of a parietal bone, temporal bones or an occipital bone of the wearer.

Example 25 includes the headgear securement system as defined in any of Examples 17-24, wherein the second end of the first arm is connected to the headgear at a first attachment point and wherein the second end of the second arm is connected to the headgear at a second attachment point.

Example 26 includes the headgear securement system as defined in any of Examples 17-25, wherein the first attachment point is provided at a first lateral portion of the headgear or a first rear portion of the headgear and wherein the second attachment point is provided at a second lateral portion of the headgear or a second rear portion of the headgear.

Example 27 is a wearable device including a first support at a fore region of the wearable device, a second support, separate from the first support, at an aft region of the wearable device, a closure connected to the second support to lock the second support at a selected one of a plurality of fit settings and a compliance mechanism connected to the second support.

Example 28 includes the wearable device in Example 27, further including a display device.

Example 29 includes the wearable device in Example 27 or Example 28, wherein the compliance mechanism includes one or more resilient elements to permit displacement of the second support to facilitate donning and doffing of the wearable device with the closure being locked at a selected fit setting.

Example 30 includes the wearable device in any of Examples 27-29, wherein the closure includes a hook and loop closure, a snap closure, or a ratchet.

Example 31 includes the wearable device in any of Examples 27-30, wherein the compliance mechanism includes a first resilient element coupled, at a first end, to a first end of a first positioner and coupled, at a second end, to a first connector of a first arm of the second support to bias the first connector against the first end of the first positioner and a second resilient element coupled, at a first end, to a first end of a second positioner and coupled, at a second end, to a second connector of a second arm of the second support to bias the second connector against the first end of the second positioner, wherein, in a locked position of the closure, the first connector is movable from the second end of the first positioner toward the first end of the first positioner against a bias of the first resilient element and the second connector is movable from the second end of the second positioner toward the first end of the second positioner against a bias of the second resilient element to facilitate donning and doffing of the wearable device with a locked closure.

Example 32 is a compliance mechanism for headgear including a first resilient element coupled, at a first end, to a first end of a first positioner and coupled, at a second end, to a first connector of a first arm of a headgear support to bias the first connector against the first end of the first positioner, a second resilient element coupled, at a first end, to a first end of a second positioner and coupled, at a second end, to a second connector of a second arm of a headgear support to bias the second connector against the first end of the second positioner and a closure having a plurality of fit settings to secure the headgear to a wearer's head and to lock a position of the first positioner relative to the second positioner, wherein, in a locked position of the closure, the first connector is movable from the second end of the first positioner toward the first end of the first positioner against a bias of the first resilient element and the second connector is movable from the second end of the second positioner toward the first end of the second positioner against a bias of the second resilient element to facilitate donning and doffing of the headgear with a locked closure.

Example 33 includes the compliance mechanism device of Example 32, wherein the first resilient element and the second resilient element include springs.

Example 34 includes the compliance mechanism device of any of Examples 32-33, wherein the first positioner includes a first gear rack, the second positioner includes a second gear rack, and the closure includes a ratchet having a pinion operatively engaging the first gear rack and the second gear rack and a lock to lock the pinion at a selected position.

Example 35 includes the compliance mechanism device of any of Examples 32-33, further including a guide member including a first groove to support and guide the first arm and a second groove to support and guide the second arm.

Example 36 is a method of fabricating a compliance mechanism, including disposing a first resilient element between a first end of a first arm and a first base member of a first positioner, disposing a second resilient element between a first end of a second arm and a first base member of a second positioner, connecting a movable member to the first positioner and the second positioner to move the first positioner relative to the second positioner, connecting a control member to the movable member and connecting a closure to the control member to enable the control member to selectively lock a position of the first positioner relative to the second positioner in a position set by the control member.

Example 37 includes the method of Example 36, wherein the first positioner includes a first gear rack and the second positioner includes a second gear rack, wherein the closure includes a ratchet, and wherein the control member includes a pinion operatively engaging the first gear rack and the second gear rack.

Example 38 includes the method of Example 36 or Example 37, wherein the first resilient element includes a first spring and wherein the second resilient element includes a second spring.

Although certain example methods, apparatus and articles of manufacture have been disclosed herein, the scope of coverage of this patent is not limited thereto. On the contrary, this patent covers all methods, apparatus and articles of manufacture fairly falling within the scope of the claims of this patent.

What is claimed is:

1. A headgear securement system, comprising:
a first support at a first portion of the headgear;
a second support, separate from the first support, at a second portion of the headgear;
a closure connected to the second support to lock the second support at a selected one of a plurality of fit settings; and
a compliance mechanism connected to the second support.

2. The system of claim 1, wherein the compliance mechanism includes one or more resilient elements to permit displacement of the second support to facilitate donning and doffing of the headgear with the closure being locked at a selected fit setting.

3. The system of claim 2, wherein the headgear includes a display device.

4. The system of claim 2, wherein the closure includes a hook and loop closure, a snap closure, or a ratchet.

5. The system of claim 2, wherein the second support includes a first arm having a first end connected to the compliance mechanism and a second end connected to the headgear and includes a second arm having a first end connected to the compliance mechanism and a second end connected to the headgear.

6. The system of claim 5, wherein the closure includes the compliance mechanism.

7. The system of claim 6,
wherein the one or more resilient elements includes a first resilient element and a second resilient element,
wherein the first resilient element is disposed between a first end of the first arm and a first end of a first positioner in a first portion of the compliance mechanism,
wherein the first end of the first arm is disposed to translate between the first end of the first positioner and a second end of the first positioner,
wherein the second resilient element is disposed between a first end of the second arm and a first end of a second positioner in a second portion of the compliance mechanism, and
wherein the first end of the second arm is disposed to translate between the first end of the second positioner and a second end of the second positioner.

8. The system of claim 7, wherein the first positioner includes a first gear rack and the second positioner includes a second gear rack.

9. The system of claim 8, further including:
a pinion operatively engaging the first gear rack and the second gear rack;
a ratchet; and
a rotatable control member controlling movement of the ratchet and the pinion,
wherein rotation of the rotatable control member rotates the pinion to cause a lateral translation of the first gear rack in a first direction and a lateral translation of the second gear rack in a second direction.

10. The system of claim 9,
wherein the first resilient element is coupled at a first end to a first end of the first arm, and
wherein the second resilient element is coupled at a first end to a first end of the second arm.

11. A headgear securement system, comprising:
a first support means at a first portion of the headgear;
a second support means, separate from the first support means, at a second portion of the headgear;
a closure means connected to the second support means to lock the second support means at a selected one of a plurality of fit settings; and
a compliance means connected to the second support means.

12. The system of claim 11, wherein the compliance means includes a resilient means to permit displacement of the second support means to facilitate donning and doffing of the headgear with the closure means being locked at a selected fit setting.

13. The system of claim 12, wherein the headgear includes a display means.

14. The system of claim 12, wherein the second support means includes a first arm having a first end connected to the compliance means and a second end connected to the headgear and wherein the second support means includes a second arm having a first end connected to the compliance means and a second end connected to the headgear.

15. The system of claim 12, wherein the first portion of the headgear includes a fore region of the headgear and the second portion of the headgear includes an aft region of the headgear.

16. The system of claim 15, wherein the first support means is to support a first portion of a weight of the headgear by directing a first portion of the weight to a frontal bone of a wearer and wherein the second support means is to support a second portion of the weight of the headgear by directing a second portion of the weight to at least one of a parietal bone, temporal bones or an occipital bone of the wearer.

17. A wearable device, comprising:
a first support at a fore region of the wearable device;
a second support, separate from the first support, at an aft region of the wearable device;
a closure connected to the second support to lock the second support at a selected one of a plurality of fit settings; and
a compliance mechanism connected to the second support.

18. The device of claim 17, including a display device.

19. The device of claim 17, wherein the compliance mechanism includes one or more resilient elements to permit displacement of the second support to facilitate donning and doffing of the wearable device with the closure being locked at a selected fit setting.

20. The device of claim 19, wherein the compliance mechanism includes a first resilient element coupled, at a first end, to a first end of a first positioner and coupled, at a second end, to a first connector of a first arm of the second support to bias the first connector against the first end of the first positioner and a second resilient element coupled, at a first end, to a first end of a second positioner and coupled, at a second end, to a second connector of a second arm of the second support to bias the second connector against the first end of the second positioner, wherein, in a locked position of the closure, the first connector is movable from the second end of the first positioner toward the first end of the first positioner against a bias of the first resilient element and the second connector is movable from the second end of the second positioner toward the first end of the second positioner against a bias of the second resilient element to facilitate donning and doffing of the wearable device with a locked closure.
